(19) United States
(12) Patent Application Publication
(10) Pub. No.: US 2007/0173025 A1
(43) Pub. Date: Jul. 26, 2007

(54) Semiconductor device and method for fabricating the same

(76) Inventor: Susumu Akamatsu, Osaka (JP)

Correspondence Address: MCDERMOTT WILL & EMERY LLP, 600 13TH STREET, N.W., WASHINGTON, DC, 20005-3096, US

(21) Appl. No.: 11/540,762

(22) Filed: Oct. 2, 2006

(30) Foreign Application Priority Data
Jan. 25, 2006 (JP) JP 2006-016217

(51) Int. Cl. H01L 21/336

(52) U.S. Cl. 438/305

(57) ABSTRACT

First and second gate portions each made of a gate insulating film, a silicon film, and a protective film are formed on a semiconductor substrate. Then, a first sidewall insulating film is formed on each of the side surfaces of the first and second gate portions. Subsequently, the protective film is removed such that the silicon film is exposed. A thermal process is performed with respect to a Ni film deposited on the silicon film to convert the silicon film to a NiSi film and then an insulating film is formed on the NiSi film. Thereafter, a Ni film is deposited on the NiSi film and a thermal process is performed to convert the NiSi film to a Ni₃Si film.

### CROSS REFERENCE TO RELATED APPLICATIONS

The teachings of Japanese Patent Application JP 2006-016217, filed Jan. 25, 2006, are entirely incorporated herein by reference, inclusive of the claims, specification, and drawings.

### BACKGROUND OF THE INVENTION

The present invention relates to a semiconductor device and a method for fabricating the same and, more particularly, to a semiconductor device comprising two types of MIS transistors having respective gate electrodes made of different metal silicide films and a method for fabricating the same.

In recent years, as a semiconductor integrated circuit device has become higher in integration, functionality, and operating speed, a technology which uses a high dielectric constant material for the gate insulating film thereof has been increasingly proposed. The reason for this is that the use of the high dielectric constant gate insulating film allows an increase in the physical thickness of the film and thereby suppresses a leakage current, while also allowing a reduction in the electrical thickness of the film and an increase in the driving force of a transistor

However, when a high dielectric constant material is used for the gate insulating film of a conventionally used polysilicon gate electrode, the problem is encountered that the threshold voltage thereof is fixed at an extremely high level due to a phenomenon termed “Fermi level pinning”.

To overcome the problem, it has been examined to use a metal or metal silicide which is free from the phenomenon of Fermi level pinning as a replacement for the polysilicon gate electrode.

However, when a gate electrode made of a metal or metal silicide is applied to a complementary MIS transistor, the respective gate electrodes of the N-type MIS transistor and the P-type MIS transistor have the same work function so that it becomes difficult to control the threshold voltage such that is has a proper value.

To properly control the threshold voltage, it becomes necessary to adjust the work functions of the gate electrodes each made of a metal or metal silicide. However, in contrast to the polysilicon gate electrode of which the work function can be changed easily by adjusting an impurity concentration in polysilicon, there is no method that allows easy adjustment of the work function of a gate electrode made of a metal or metal silicide. Therefore, various methods have been proposed at present for this purpose.

Among them, a technology which controls the threshold voltage by forming gate electrodes of metal suicides and varying the respective compositions ratios of the metal silicides in the N-type and P-type MIS transistors has been proposed.

Since the method can form the metal silicides by depositing a metal film on a polysilicon film and then performing a thermal process to cause silicidation, it has high compatibility with a conventional process and receives attention as a promising technology in terms of its application to a complementary MIS transistor.

As has been known, the relationship between the composition ratio of a metal silicide and the work function thereof is such that, when a nickel silicide is used as an example, the work function is higher as the ratio of nickel is higher. Specifically, NiSi, Ni₂Si, and Ni₃Si have progressively higher work functions in this order.

When a nickel silicide is formed by depositing a nickel film (with a thickness of t_{Ni}) on a polysilicon film (with a thickness of t_{Si}) and performing a thermal process to cause silicidation, an approach of varying the thickness ratio (t_{Ni}/t_{Si}) between the polysilicon film and the nickel film and thereby obtaining a nickel silicide with a desired composition ratio has been commonly known.

A description will be given herein below to a specific method for forming nickel silicide films having different composition ratios.

FIGS. 8A and 8B are step cross-sectional views illustrating a method for forming nickel silicide films disclosed in Non-Patent Document 1 (S. Hase et al., “HfSiON Gate Insulating Film MOSFET Using Composition-Controlled Fully Silicided Electrodes”, SEMI FORUM JAPAN 2005, pages 47 to 60).

As shown in FIG. 8A, patterned polysilicon films 103a and 103b are formed on the portions of a semiconductor substrate 101 corresponding to the respective gate regions of N-type and P-type MIS transistors with respective gate insulating films 102 interposed therebetween. On the portion of the semiconductor substrate 101 on which the polysilicon films 103a and 103b are not formed, a planarized insulating film 104 is formed.

After a nickel film 105a is deposited over the entire surface of the semiconductor substrate 101, an insulating film 106 is formed selectively over the gate region of the N-type MIS transistor and a nickel film 105b is deposited again over the entire surface of the semiconductor substrate 101.

Thereafter, as shown in FIG. 8B, a thermal process is performed with respect to the semiconductor substrate 101, thereby causing a reaction between the polysilicon film 103a and the nickel film 105a and forming a nickel silicide film 107a on the gate region of the N-type MIS transistor, while causing a reaction between the polysilicon film 103b and the nickel films 105a and 105b in a multilayer structure and forming a nickel silicide film 107b on the gate region of the P-type MIS transistor.

As shown in FIG. 8A, the thickness ratio (t_{Ni}/t_{Si}) between the nickel film 105a and the polysilicon film 103a in the gate region of the N-type MIS transistor has been set to be lower than the thickness ratio (t_{Ni}/t_{Si}) between the multilayer nickel films 105a and 105b and the polysilicon film 103b in the gate region of the P-type MIS transistor. Accordingly, the nickel silicide film 107a formed on the gate region of the N-type MIS transistor is made of NiSi or Ni₂Si, while the nickel silicide film 107b formed on the gate region of the P-type MIS transistor is made of Ni₃Si.

Since the insulating film 106 is formed over the gate region of the N-type MIS transistor, nickel is prevented from being diffused from the nickel film 105b deposited on the insulating film 106 into the polysilicon film 103a during the thermal process. In accordance with the method, the two nickel silicide films having different composition ratios can be formed simultaneously in one thermal process. Therefore, the process steps of the method can be simplified suitably for mass production.

However, to form the nickel silicide film 107b made of Ni₃Si by causing a reaction between the polysilicon film 103b and the multilayer nickel films 105a and 105b in the gate region of the P-type MIS transistor in accordance with the method, it is necessary to perform the thermal process for a long period of time, as can be seen from FIG. 8A. At this time, the thermal process is also performed for a long period of time to cause the reaction between the polysilicon film 103a and the nickel film 105a in the gate region of the N-type MIS transistor. Accordingly, even when the nickel film 105a on the polysilicon film 103a is thin, nickel is laterally diffused from the portion of the nickel film 105a which is formed on the adjacent insulating film 104 and from the thick multilayer nickel films 105a and 105b formed over the gate region of the adjacent P-type MIS transistor as a result of the long-period thermal process. Consequently, the composition ratio of the nickel silicide film 107a formed on the gate region of the N-type MIS transistor changes to be Ni-richer. In particular, when the miniaturization of the complementary MIS transistor proceeds, the thick multilayer nickel films 105a and 105b are formed in close proximity to the gate region of the N-type MIS transistor. As a result, it becomes difficult to precisely control the composition ratio of the nickel silicide film 107a.

When the nickel silicide films 107a and 107b are formed by siliciding the polysilicon films 103a and 103b in accordance with the method, volume expansion occurs to actually produce an undesirable level difference between the gate regions, though it is not shown in FIG. 8B. In particular, the volume expansion is greater as the composition ratio is Ni-richer. In addition, the polysilicon films 103a and 103b have equal thicknesses and the multilayer nickel films 105a and 105b over the gate region of the P-type MIS transistor have a combined thickness which is larger than the thickness of the nickel film 105a over the gate region of the N-type MIS transistor. Accordingly, the nickel silicide film (Ni₃Si) 107b serving as the gate electrode of the P-type MIS transistor is higher in level than the nickel silicide film (NiSi) 107a serving as the gate electrode of the N-type MIS transistor, so that a large level difference is produced disadvantageously between the two electrodes.

The method disclosed in Non-Patent Document 1 submitted by Hase et al. adjusts the thickness ratio (t_{Ni}/t_{Si}) between the nickel film and the polysilicon film by holding the thickness (t_{Si}) of the polysilicon film constant and varying the thickness (t_{Ni}) of the nickel film. By contrast, a method which adjusts the film thickness ratio (t_{Ni}/t_{Si}) by holding the thickness (t_{Ni}) of the nickel film constant and varying the thickness (t_{Si}) of the polysilicon film is disclosed in Non-Patent Document 2 (A. Lauwers et al., “CMOS Integration of Dual Work Function Phase Controlled Ni FUSI with Simultaneous Silicidation of NMOS (NiSi) and PMOS (Ni-rich Silicide) Gates on HfSiON”, IEDM Tech. Dig. 2005, pages 661-664). Referring to FIGS. 9A to 9D, the method disclosed in Non-Patent Document 2 submitted by Lauwers et al. will be described herein below.

As shown in FIG. 9A, patterned polysilicon films 202a and 202b are formed on the portions of a semiconductor substrate 201 corresponding to the respective gate regions of N-type and P-type MIS transistors with respective gate insulating films (not shown) interposed therebetween. Thereafter, sidewall insulating films 203 are formed on the respective sidewalls of the polysilicon films 202a and 202b. Then, an insulating film 204 is formed on the portion of the semiconductor substrate 201 in which the polysilicon films 202a and 202b are not formed.

Next, as shown in FIG. 9B, the polysilicon film 202b formed on the gate region of the P-type MIS transistor is partially removed by etching using a resist film 205 selectively formed over the gate region of the N-type MIS transistor as a mask.

Next, as shown in FIG. 9C, the resist film 205 is removed and then a nickel film 206 is deposited over the entire surface of the semiconductor substrate 201. At this time, the nickel film 206 is formed to have a part thereof buried in a depressed portion surrounded by the sidewall insulating film 203 of the P-type MIS transistor and located over the polysilicon film 202b in the depressed portion.

Finally, as shown in FIG. 9D, a thermal process is performed with respect to the semiconductor substrate 201, thereby causing a reaction between the polysilicon film 202a and the nickel film 206 and forming a nickel silicide film 207a on the gate insulating film of the N-type MIS transistor, while simultaneously causing a reaction between the polysilicon film 202b and the nickel film 206 and forming a nickel silicide film 207b on the gate insulating film of the P-type MIS transistor. At this time, a nickel silicide film 207c which is Ni-richer than the nickel silicide film 207a is occasionally formed on the nickel silicide film 207a.

As shown in FIG. 9C, the thickness ratio (t_{Ni}/t_{Si}) between the nickel film 206 and the polysilicon film 202a in the gate region of the N-type MIS transistor is lower than the thickness ratio (t_{Ni}/t_{Si}) between the nickel film 206 and the polysilicon film 202b in the gate region of the P-type MIS transistor. As a result, the nickel silicide film 207a formed in the gate region of the N-type MIS transistor is made of NiSi, while the nickel silicide film 207b formed in the gate region of the P-type MIS transistor is made of Ni₃Si. Thus, the nickel silicide films 207a and 207b having the different composition ratios are formed on the respective gate insulating films of the N-type and P-type MIS transistors.

### SUMMARY OF THE INVENTION

The method disclosed in Non-Patent Document 2 is superior to that disclosed in Non-Patent Document 1 in that the composition ratios of the nickel silicide films are less likely to fluctuate since the nickel film deposited over the polysilicon films has an equal thickness.

However, since the thickness of the polysilicon film on the gate region of the P-type MIS transistor has been reduced by etching, fluctuations are likely to occur in the thickness of the polysilicon film after etching. In particular, the polysilicon film is formed in the region surrounded by the sidewall insulating film and etched by an etch-back process which is performed within the region surrounded by the sidewall insulating film (see FIG. 9B). Therefore, it is not easy to precisely control an amount of etching and the formation of the metal silicide film having a stable composition ratio becomes difficult.

Since the polysilicon film in the gate region of the P-type MIS transistor has been thinned, volume expansion resulting from silicidation is smaller than in the method disclosed in Non-Patent Document 1. However, the difference in magnitude between volume expansion in the N-type MIS transistor and that in the P-type MIS transistor causes a level difference between the respective gate electrodes of the N-type and P-type MIS transistors.

Thus, a method which forms metal silicides having different composition ratios by depositing a metal film over polysilicon films having different thicknesses and then performing a thermal process to cause silicidation has excellent process compatibility with a conventional process and is therefore a promising technology in terms of its application to a complementary MIS transistor. To apply the method to a mass production process, however, problems associated with the controllability of composition ratios, the planarity of gate electrodes, and the like still remain to be solved.

The present invention has been achieved in view of the foregoing and it is therefore an object of the present invention to provide a semiconductor device including two types of MIS transistors having respective gate electrodes made of different metal silicide films and formed to have stable composition ratios and excellent planarity and a method for fabricating the same.

A semiconductor device according to the present invention is a semiconductor device comprising a first MIS transistor and a second MIS transistor, wherein the first MIS transistor comprises: a first gate portion having a first gate insulating film formed on a semiconductor substrate and a first gate electrode made of a first metal silicide film formed on the first gate insulating film; a first sidewall insulating film formed on each of side surfaces of the first gate portion; and an insulating film formed on the semiconductor substrate in lateral relation to the first sidewall insulating film and the second MIS transistor comprises: a second gate portion having a second gate insulating film formed on the semiconductor substrate and a second gate electrode made of a second metal silicide film formed on the second gate insulating film; a second sidewall insulating film formed on each of side surfaces of the second gate portion; and the insulating film formed on the semiconductor substrate in lateral relation to the second sidewall insulating film, wherein respective upper surfaces of the first and second gate portions are planarized to be flush with an upper surface of the insulating film.

In the arrangement, the respective gate portions of the first and second MIS transistors have the upper surfaces thereof planarized to be flush with the upper surface of the insulating film formed in lateral relation to the sidewall insulating films. This makes it possible to obtain the semiconductor device including the two types of MIS transistors having respective threshold voltages accurately controlled and made of the different metal silicide films with excellent planarity.

In a preferred embodiment, the first gate portion is preferably made of the first gate insulating film, the first gate electrode, a protective insulating film formed on the first gate electrode, and a metal film formed on the protective insulating film.

In another preferred embodiment, the second gate portion is preferably made of the second gate insulating film, the second gate electrode, and a third sidewall insulating film formed on an upper portion of each of inner side surfaces of the second sidewall insulating film.

In still another preferred embodiment, the second gate portion preferably further comprises the metal film formed on the second metal silicide film.

In yet another preferred embodiment, an upper surface of the first metal silicide film is preferably lower in level than an upper surface of the second metal silicide film.

In still another preferred embodiment, the first gate portion is preferably made of the first gate insulating film and the first gate electrode and the second gate portion is preferably made of the second gate insulating film and the second metal silicide film.

In yet another preferred embodiment, the first gate portion is preferably made of the first gate insulating film and the first gate electrode and the second gate portion is preferably made of the second gate insulating film, the second metal silicide film, and a metal film formed on the second metal silicide film.

In still another preferred embodiment, the second metal silicide film is preferably metal-richer than the first metal silicide film.

In yet another preferred embodiment, the first meal silicide film is preferably made of NiSi or Ni₂Si and the second metal silicide film is made of Ni₃Si.

In still another preferred embodiment, the first MIS transistor is preferably an N-type MIS transistor and the second MIS transistor is preferably a P-type MIS transistor.

A method for fabricating a semiconductor device according to the present invention is a method for fabricating a semiconductor device comprising a first MIS transistor having a first gate portion and a second MIS transistor having a second gate portion, the method comprising the steps of: (a) forming, on a semiconductor substrate, the first gate portion made of a first gate insulating film, a first silicon film, and a first protective film and the second gate portion made of a second gate insulating film, a second silicon film, and a second protective film; (b) forming a first sidewall insulating film on each of side surfaces of the first gate portion and forming a second sidewall insulating film on each of side surfaces of the second gate portion; (c) after the step (b), forming an insulating film on the semiconductor substrate and then planarizing the insulating film to expose respective upper surfaces of the first and second protective films; (d) after the step (c), selectively removing the first and second protective films from the first and second gate portions; (e) after the step (d), siliciding the entire first silicon film to form a first metal silicide film; (f) after the step (d), siliciding the entire second silicon film to form a second metal silicide film; and (g) after the steps (e) and (f), planarizing respective upper surfaces of the first and second gate portions such that they are flush with an upper surface of the insulating film, wherein the first gate portion of the first MIS transistor has the first gate insulating film and a first gate electrode made of the first metal silicide film and the second gate portion of the second MIS transistor has the second gate insulating film and a second gate electrode made of the second metal silicide film.

The arrangement allows the formation of the two types of MIS transistors having respective threshold voltages accurately controlled and made of the different metal silicide films with excellent planarity by forming the gate electrodes made of the different metal silicide films in the regions of the respective gate portions of the first and second MIS transistors which are surrounded by the sidewall insulating films and planarizing the respective upper surfaces of the gate portions such that they are flush with the upper surface of the insulating film formed in lateral relation to the sidewall insulating films.

In a preferred embodiment, the step (e) preferably includes the step of siliciding the entire second silicon film to form a metal silicide film, while simultaneously forming the first metal silicide film, each through silicidation using a first metal film, the method preferably further comprising the step of: (h) after the step (e) and before the step (f), forming a protective insulating film covering an upper surface of the first metal silicide film, wherein the step (f) preferably includes the step of converting the metal silicide film to the second metal silicide film through silicidation using a second metal film, the step (g) preferably includes the step of performing planarization by polishing away the portion of the second metal film which is located on the insulating film and thereby locally leaving the second metal film on the protective insulating film, the first gate portion of the first MIS transistor is preferably made of the first gate insulating film, the first gate electrode, the protective insulating film formed on the first gate electrode, and the second metal film formed on the protective insulating film, and the second gate portion of the second MIS transistor is preferably made of the second gate insulating film and the second gate electrode.

In another preferred embodiment, the step (g) preferably includes the step of polishing away the portion of the second metal film which is located on the insulating film and thereby locally leaving the second metal film on the second metal silicide film and the second gate portion of the second MIS transistor is preferably made of the second gate insulating film, the second gate electrode, and the second metal film.

In still another preferred embodiment, the method preferably further comprises the steps of: (i) before the step (a), forming a gate insulating film on the semiconductor substrate; (j) forming, on the gate insulating film, a first silicon forming film having a first thickness and a second silicon forming film having a second thickness smaller than the first thickness; and (k) forming a protective film having a planarized surface over the first and second silicon forming films, wherein the step (a) preferably includes the step of patterning the protective film, the first and second silicon forming films, and the gate insulating film to form the first and second protective films each made of the protective film, the first silicon film made of the first silicon forming film, the second silicon film made of the second silicon forming film, and the first and second gate insulating films each made of the gate insulating film, the steps (e) and (f) preferably include the step of performing silicidation by using a metal film to simultaneously form the first and second metal silicide films, and the step (g) preferably includes performing planarization by polishing away the portion of the metal film which is located on the insulating film.

In yet another preferred embodiment, the step (g) preferably includes the step of polishing away the portion of the metal film which is located on the insulating film and thereby leaving the metal film on the second metal silicide film and the second gate portion of the second MIS transistor is preferably made of the second gate insulating film, the second gate electrode, and the metal film.

In still another preferred embodiment, the second metal silicide film is preferably metal-richer than the first metal silicide film.

In yet another preferred embodiment, the first meal silicide film is preferably made of NiSi or Ni₂Si and the second metal silicide film is made of Ni₃Si.

In still another preferred embodiment, the first MIS transistor is preferably an N-type MIS transistor and the second MIS transistor is preferably a P-type MIS transistor.

In the semiconductor device and the method for fabricating the same according to the present invention, the first gate portion of the first MIS transistor having the first gate electrode made of the first metal silicide film and the second gate portion of the second MIS transistor having the second gate electrode made of the second metal silicide film have the respective upper surfaces thereof planarized to be flush with the upper surface of the insulating film. This makes it possible to provide the semiconductor device including the two types of MIS transistors having respective threshold voltages accurately controlled and the respective gate electrodes made of the different metal silicide films with excellent planarity.

### BRIEF DESCRIPTION OF THE DRAWINGS

FIGS. 1A to 3C are step cross-sectional views schematically illustrating a method for fabricating a complementary MIS transistor according to a first embodiment of the present invention;

FIG. 4 is a cross-sectional view showing a complementary MIS transistor according to a variation of the first embodiment;

FIGS. 5A to 6C are step cross-sectional views schematically illustrating a method for fabricating a complementary semiconductor device according to a second embodiment of the present invention;

FIG. 7 is a cross-sectional view showing a complementary MIS transistor according to a variation of the second embodiment;

FIGS. 8A and 8B are step cross-sectional views illustrating a method for fabricating a conventional complementary MIS transistor; and

FIGS. 9A to 9D are cross-sectional views illustrating a method for fabricating another conventional complementary MIS transistor.

### DETAILED DESCRIPTION OF THE PREFERRED EMBODIMENTS

Referring to the drawings, the embodiments of the present invention will be described herein below. Throughout the accompanying drawings, components having substantially the same functions will be denoted by the same reference numerals for the sake of simple illustration. It is to be noted that the present invention is not limited to the following embodiments.

### Embodiment 1

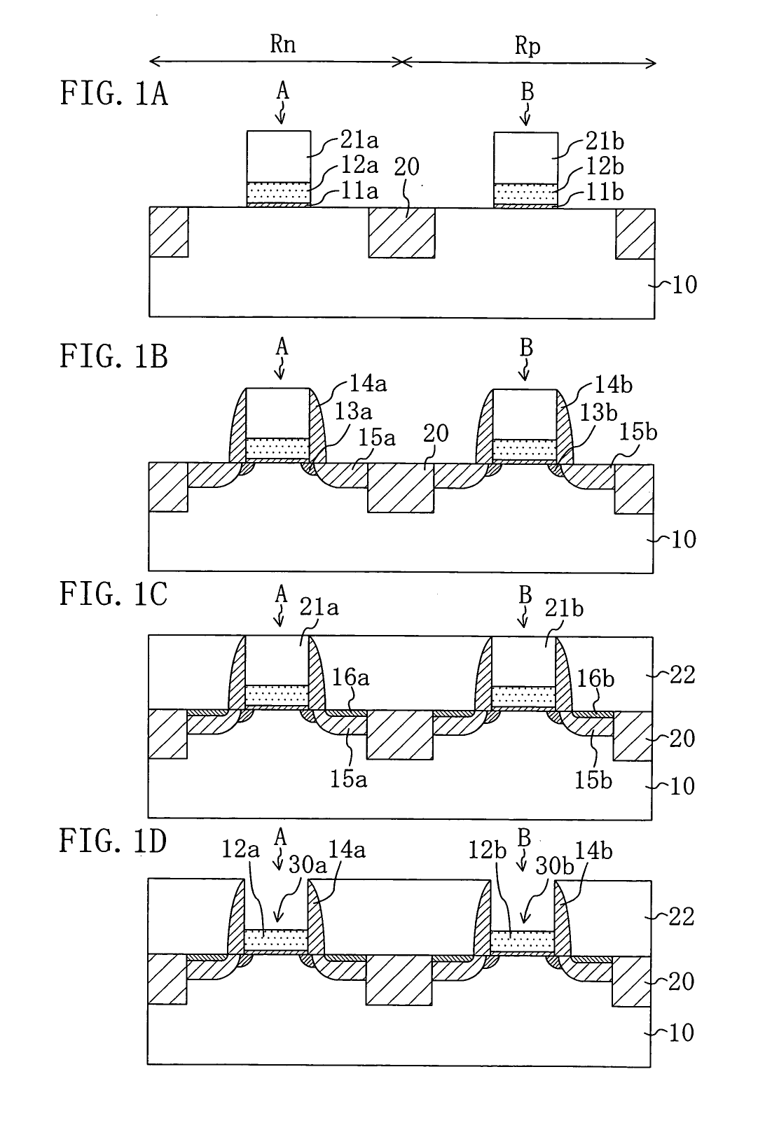

FIGS. 1A to 3C are step cross-sectional views schematically illustrating a method for fabricating a complementary MIS transistor according to the first embodiment of the present invention. Each of the drawings shows an N-type MIS transistor formation region Rn on the left-hand side and a P-type MIS transistor formation region Rp on the right-hand side.

First, as shown in FIG. 1A, an isolation region 20 is formed in a semiconductor substrate 10 made of silicon to define the respective active areas of the N-type and P-type MIS transistor formation regions Rn and Rp. Then, a P-type well (not shown) is formed in the N-type MIS transistor formation region Rn of the semiconductor substrate 10 and an N-type well (not shown) is formed in the P-type MIS transistor formation region Rp of the semiconductor substrate 10. Subsequently, a gate insulating film made of a high dielectric constant material such as HfO₂ or HfSiON and having a thickness of 1.7 nm is formed over the entire surface of the semiconductor substrate 10. Then a polysilicon film with a thickness of 40 nm is formed on the gate insulating film. Thereafter, a protective film composed of a CVD-oxide film with a thickness of 80 nm is formed on the polysilicon film.

Then, anisotropic etching is performed successively with respect to the protective film, the polysilicon film, and the gate insulating film to form a first gate portion A composed of a first gate insulating film 11a, a first silicon film 12a, and a first protective film 21a on the portion of the semiconductor substrate 10 corresponding to the active area of the N-type MIS transistor formation region Rn and also form a second gate portion B composed of a second gate insulating film 11b, a second silicon film 12b, and a second protective film 21b on the portion of the semiconductor substrate 10 corresponding to the active area of the P-type MIS transistor formation region Rp. In the present embodiment, the isolation region 20 has a shallow trench isolation (STI) structure in which an insulating film is buried in a trench formed in the semiconductor substrate 10.

Next, as shown in FIG. 1B, an n-type impurity (e.g., As ions) is selectively implanted in the active area of the N-type MIS transistor formation region Rn by using the first gate portion A as a mask, thereby forming n-type extension regions 13a by self alignment in the respective portions of the semiconductor substrate 10 which are located on both lateral sides of the first gate portion A. On the other hand, a p-type impurity (e.g., BF₂ ions) is selectively implanted in the active area of the P-type MIS transistor formation region Rp by using the second gate portion B as a mask, thereby forming p-type extension regions 13b by self alignment in the respective portions of the semiconductor substrate 10 which are located on both lateral sides of the second gate portion B.

Then, first and second sidewall insulating films 14a and 14b each made of a silicon nitride film are formed on the respective side surfaces of the first and second gate portions A and B. Thereafter, an n-type impurity (e.g., As ions) is selectively implanted into the active area of the N-type MIS transistor formation region Rn by using the first gate portion A and the first sidewall insulating film 14a as a mask, thereby forming n-type source/drain regions 15a by self alignment in the respective portions of the semiconductor substrate 10 which are located laterally to the first sidewall insulating film 14a. On the other hand, a p-type impurity (e.g., B ions) is selectively implanted into the active area of the P-type MIS transistor formation region Rp by using the second gate portion B and the second sidewall insulating film 14b as a mask, thereby forming p-type source/drain regions 15b by self alignment in the respective portions of the semiconductor substrate 10 which are located laterally to the second sidewall insulating film 14b.

Next, as shown in FIG 1C, silicide films 16a and 16b each made of, e.g., a Ni silicide are formed by using a salicide technology on the n-type source/drain regions 15a and on the p-type source/drain regions 15b, respectively. Then, an insulating film 22 composed of a planarized CVD-oxide film is formed on the portion of the semiconductor substrate 10 on which the first and second gate portions A and B are not formed. The planarization can be performed by, e.g., depositing the insulating film 22 over the entire surface of the semiconductor substrate 10 and then polishing the insulating film 22 by CMP (Chemical Mechanical Polishing) until the respective upper surfaces of the protective films 21a and 21b are exposed.

Next, as shown in FIG ID, the protective films 21a and 21b are selectively removed from the first and second gate portion A and B such that the silicon films 12a and 12b are exposed at the respective bottom surfaces of depressed portions 30a and 30b surrounded by the sidewall insulating films 14a and 14b, respectively. The selective removal of the protective films 21a and 21b can be effected by, e.g., performing etching using an etchant with a high selectivity with respect to each of the insulating film 22, the sidewall insulating films 14a and 14b, and the silicon films 12a and 12b.

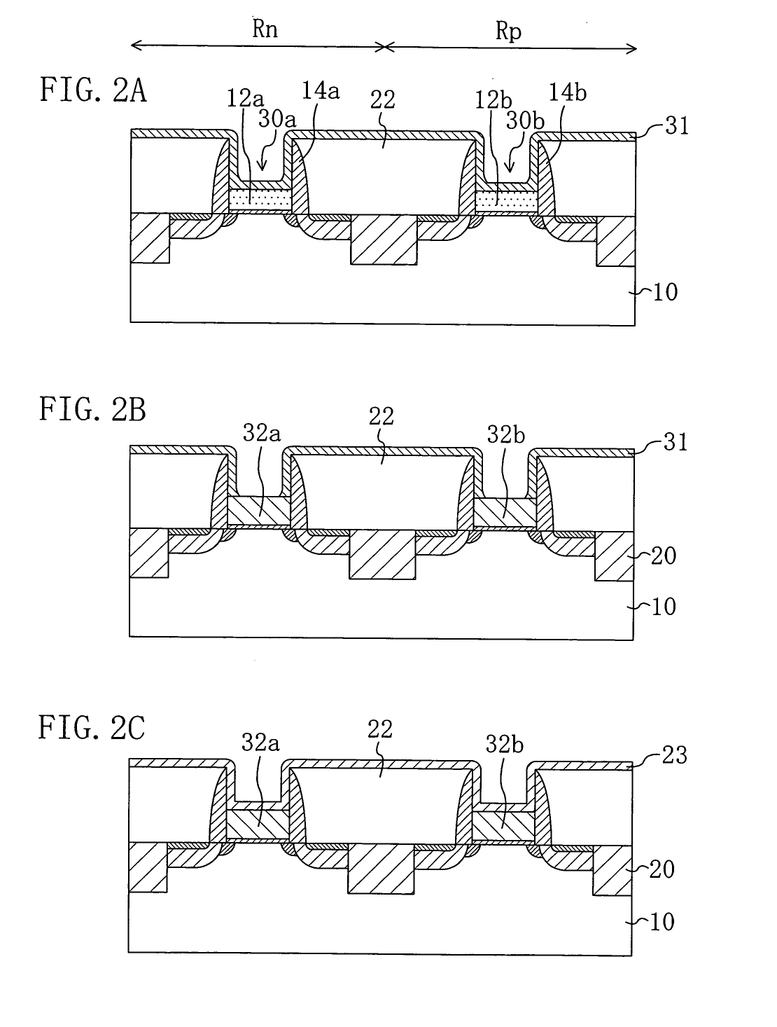

Next, as shown in FIG. 2A, a first metal film 31 with a thickness of 30 nm is formed over the entire surface of the semiconductor substrate 10. As a result, each of the silicon films 12a and 12b exposed in the respective depressed portions 30a and 30b is covered with the first metal film 31. At this time, the first metal film 31 need not necessarily be formed on the upper surface of the insulating film 22. It is sufficient for the first metal film 31 to be formed to cover at least the respective upper surfaces of the silicon films 12a and 12b in the depressed portions 30a and 30b. Preferably, the first metal film 31 is made of a refractory metal such as nickel, titanium, molybdenum, or platinum.

Next, as shown in FIG. 2B, a reaction is caused between each of the silicon films 12a and 12b and the first metal film 31 by performing a thermal process with respect to the semiconductor substrate 10, thereby entirely siliciding the silicon films 12a and 12b and converting them into first metal silicide films 32a and 32b. At this time, the first metal silicide films 32a and 32b are formed through the reaction caused between each of the silicon films 12a and 12b and the first metal film 31 by the thermal process. The thickness ratio between each of the silicon films 12a and 12b and the first metal film 31 is preliminarily set to provide the metal silicide films having desired composition ratios. For example, when the first metal film 31 is made of a nickel (Ni) material, the film thickness ratio is preferably set such that a composition ratio represented by NiSi or Ni₂Si is provided between Ni and Si in each of the first metal silicide film 32a and 32b.

Next, as shown in FIG. 2C, the unreacted portion of the first metal film 31 is removed and then an insulating film 23 composed of a CVE-nitride film with a thickness of 10 nm is formed over the entire surface of the semiconductor substrate 10.

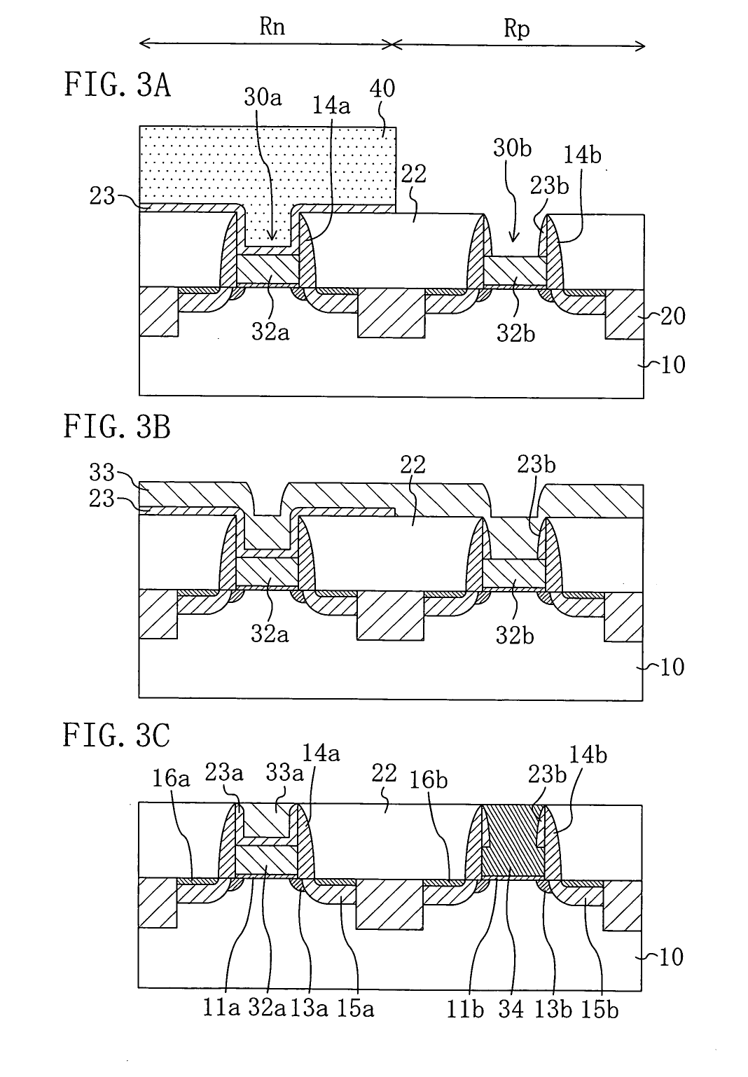

Next, as shown in FIG. 3A, a resist film 40 covering the first metal silicide film 32a in the N-type MIS transistor formation region Rn and having an opening over the first metal silicide film 32b in the P-type MIS transistor formation region Rp is formed on the insulating film 23. Then, dry etching is performed with respect to the insulating film 23 by using the resist film 40 as a mask, thereby exposing the upper surface of the first metal silicide film 32b in the P-type MIS transistor formation region Rp. As a result, the insulating film 23 remains to cover the upper surface of the first metal silicide film 32a in the N-type MIS transistor formation region Rn. At this time, a third sidewall insulating film 23b composed of the insulating film 23 also remains on each of those parts of the side surfaces of the second sidewall insulating film 14b which are located above the first metal silicide film 32b in the P-type MIS transistor formation region Rp to form the inner side surfaces of the depressed portion 30b. The third sidewall insulating film 23b need not necessarily be left. It is also possible to completely etch away the third sidewall insulating film 23b.

Next, as shown in FIG. 3B, a second metal film 33 with a thickness of 50 nm is formed over the entire surface of the semiconductor substrate 10. At this time, the second metal film 33 is preferably composed of the same metal material as composing the first metal film 31. For example, when the first metal film 31 is composed of a nickel material, the nickel material is used to compose the second metal film.

Next, as shown in FIG. 3C, a thermal process is performed with respect to the semiconductor substrate 10a to cause a reaction between the first metal silicide film 32b in the P-type MIS transistor formation region Rp and the second metal film 33 and thereby convert the entire first metal silicide film 32b to a metal-richer second metal silicide film 34. For example, when the second metal film 33 is composed of a nickel material, the second metal silicide film 34 is formed through a reaction between NiSi or Ni₂Si composing the first metal silicide film 32b and Ni composing the second metal film 33 so that a Ni-richer Ni₃Si film is formed. Thereafter, the portion of the second metal film 33 which is located on the insulating film 22 is removed by polishing using a CMP method. At this time, the portion of the insulating film 23 which remains on the insulating film 22 is also preferably removed. As a result, a structure is obtained in which the protective insulating film 23a having a depressed cross-sectional configuration and the second metal film 33a formed on the protective insulating films 23a are buried in the depressed portion 30a located above the first metal silicide films 32b.

Thus, an N-type MIS transistor having a gate portion composed of the gate insulating film 11a, the first metal silicide film 32a, the protective insulating film 23a, and the second metal film 33a is formed in the N-type MIS transistor formation region Rn, while a P-type MIS transistor having a gate portion composed of the gate insulating film lib, the second metal silicide film 34, and the sidewall insulating film 23b is formed in the P-type MIS transistor formation region Rp. The upper surface (upper surface of the second metal film 33a) of the gate portion of the N-type MIS transistor and the upper surface (upper surface of the second metal silicide film 34) of the gate portion of the P-type MIS transistor are planarized to be flush with the upper surface of the insulating film 22. It is to be noted that the sidewall insulating film 23b of the gate portion of the P-type MIS transistor need not necessarily be provided.

When the second metal silicide film 34 is formed by the thermal process in the P-type MIS transistor formation region Rp, the insulating film 23a (protective insulating film 23a) is interposed between the first metal silicide film 32a and the second metal film 33a in the N-type MIS transistor formation region Rn. This prevents the first metal silicide film 32a from being converted to the second metal silicide film 34 in the N-type MIS transistor formation region Rn.

By the fabrication method described above, the N-type MIS transistor is formed in the N-type MIS transistor formation region Rn. The N-type MIS transistor has the first gate insulating film 11a formed on the semiconductor substrate 10, a gate electrode made of the first metal silicide film 32a formed on the first gate insulating film 11a, the protective insulating film 23a formed on the first metal silicide film 32a and having a depressed cross-sectional configuration, the second metal film 33a formed in a depressed portion located above the protective insulating film 23a, the first sidewall insulating film 14a formed on each of the side surfaces of the gate electrode (first metal silicide film 32a), the n-type extension regions 13a formed in the respective portions of the semiconductor substrate 10 which are located below and on both lateral sides of the gate electrode (first metal silicide film 32a), the n-type source/drain regions 15a formed in the respective portions of the semiconductor substrate 10 which are located below and laterally to the first sidewall insulating film 14a, and the silicide film 16a formed on each of the n-type source/drain regions 15a. Each of the protective insulating film 23a and the second metal film 33a is formed over the first metal silicide film 32a in the depressed portion 30a surrounded by the first sidewall insulating film 14a and the upper surface of the second metal film 33a has been planarized to be substantially flush with the upper surface of the insulating film 22 and the upper end of the first sidewall insulating film 14a.

On the other hand, the P-type MIS transistor is formed in the P-type MIS transistor formation region Rp. The P-type MIS transistor has the second gate insulating film 11b formed on the semiconductor substrate 10, a gate electrode composed of the second metal silicide film 34 formed on the second gate insulating film 11b, the second sidewall insulating film 14b formed on each of the side surfaces of the gate electrode (second metal silicide film 34), the p-type extension regions 13b formed in the respective portions of the semiconductor substrate 10 which are located below and on both lateral sides of the gate electrode (second metal silicide film 34), the p-type source/drain regions 15b formed in the respective portions of the semiconductor substrate 10 which are located below and laterally to the second sidewall insulating film 14b, and the silicide film 16b formed on each of the p-type source/drain regions 15b. The upper surface of the second metal silicide film 34 is planarized to be substantially flush with the upper surface of the insulating film 22 and the upper end of the second sidewall insulating film 14b.

On the upper part of each of the inner side surfaces of the second sidewall insulating film 14b, the third sidewall insulating film 23b having the bottom surface thereof substantially flush with the bottom surface of the protective insulating film 23a has been formed. By thus using the different metal silicide materials to compose the respective gate electrodes of the N-type and P-type MIS transistors, the threshold voltage of the complementary MIS transistor can be controlled to have a proper value.

In particular, the method according to the present invention forms the first metal silicide film 32a as the gate electrode of the N-type MIS transistor and the second metal silicide film 34 as the gate electrode of the P-type MIS transistor by performing two independent thermal processes. This allows independent control of the respective composition ratios of the metal silicide films and thereby allows the formation of the metal silicide films (gate electrodes) having the stable composition ratios.

Typically, the composition ratio between a metal and silicon in the first metal silicide film 32a is different from the composition ratio between a metal and silicon in the second metal silicide film 34. Preferably, the first metal silicide film 32a is made of NiSi or Ni₂Si and the second metal silicide film 34 is made of Ni₃Si.

In addition, the second metal silicide film 34 of the P-type MIS transistor is formed through the solid phase reaction between the first metal silicide film 32b and the second metal film 33. This allows the volume expansion of the second metal silicide film 34 to be greatly suppressed compared with that of the metal silicide film formed through the solid phase reaction (silicidation) between the silicon film and the metal film. As a result, a complementary MIS transistor with excellent planarity can be formed.

After forming the second metal film 33 over the entire surface of the semiconductor substrate 10 in the step shown in FIG. 3B, it is also possible to planarize the second metal film 33 such that it is buried only in the depressed portions 30a and 30b in the N-type and P-type MIS transistor formation regions Rn and Rp, perform a thermal process to cause a reaction between the first metal silicide film 32b and the second metal film 33 buried in the depressed portion 30b in the P-type MIS transistor formation region Rp, and thereby convert the first metal silicide film 32b to the second metal silicide film 34.

In the arrangement also, volume expansion is hardly observed during the conversion of the first metal silicide film 32b to the second metal silicide film 34. This allows the complementary MIS transistor to retain excellent planarity.

### Variation of Embodiment 1

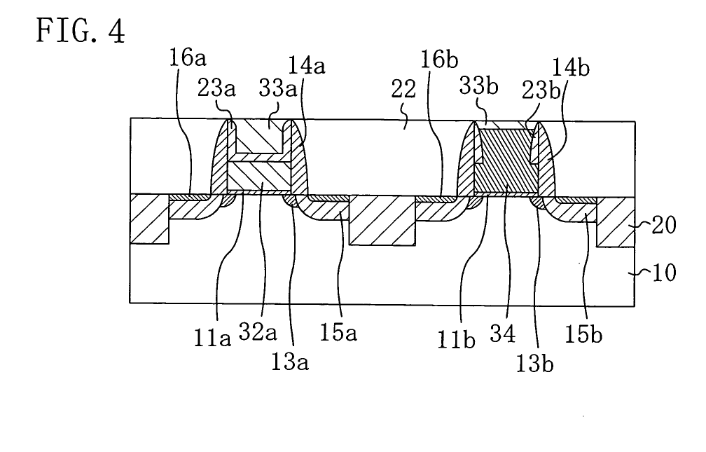

FIG. 4 is a cross-sectional view schematically showing a complementary MIS transistor according to a variation of the first embodiment.

The complementary MIS transistor shown in FIG. 4 has the same structure as the complementary MIS transistor according to the first embodiment, except that a second metal film 33b is formed on the second metal silicide film 34 of the P-type MIS transistor.

That is, as shown in FIG. 4, the gate electrode of the P-type MIS transistor is composed of the second metal silicide film 34 and the second metal film 33b. The upper surface of the second metal film 33b is planarized to be substantially flush with the upper surface of the second metal film 33a, the upper surface of the insulating film 22, and the respective upper ends of the first and second sidewall insulating films 14a and 14b.

The structure is obtained by setting the thickness of the first metal silicide film 32b and the depth of the depressed portion 30b after the step shown in FIG. 2B such that the upper surface of the second metal silicide film formed by the thermal process in the step shown in FIG. 3C is lower in level than the upper surface of the insulating film 22 and thereby allowing the second metal film 33b to be left on the second metal silicide film 34 of the P-type MIS transistor when the portion of the second metal film 33 which is located on the insulating film 22 is polished away by CMP, as shown in FIG. 4. As a result, the N-type MIS transistor having the gate portion composed of the gate insulating film 11a, the first metal silicide film 32a, the protective insulating film 23a, and the second metal film 33a is formed in the N-type MIS transistor formation region Rn, while the P-type MIS transistor having the gate portion composed of the gate insulating film 11b, the second metal silicide film 34, the second metal film 33a, and the sidewall insulating film 23b is formed in the P-type MIS transistor formation region Rp. The sidewall insulating film 23b of the gate portion of the P-type MIS transistor need not necessarily be provided.

In the arrangement, the gate electrode of the P-type MIS transistor is made of the multilayer film including the second metal silicide film 34 and the second metal film 33b. Therefore, when the resistance of the second metal silicide film 34 is higher than that of the first metal silicide film 32a, an increase in the resistance of the gate electrode of the P-type MIS transistor can be prevented by using the second metal film 33b.

### Embodiment 2

When metal silicide films having different composition ratios are simultaneously formed in a single thermal process by causing reactions between polysilicon films and metal films, the approach of varying the thickness ratios between the polysilicon films and the metal films is useful. Based on the approach, the method which varies the thickness of the metal film relative to the constant thickness of the polysilicon film and the method which varies the thickness of the polysilicon film relative to the constant thickness of the metal film are disclosed in Non-Patent Documents 1 and 2, respectively.

However, the conventional methods described above have had the problems to be solved in terms of controlling the composition ratios of the metal silicide films, the planarity of the gate electrodes, and the like, as stated previously.

The second embodiment of the present invention will provide a novel method for solving the conventional problems based on the approach mentioned above. The method will be described herein below with reference to the drawings.

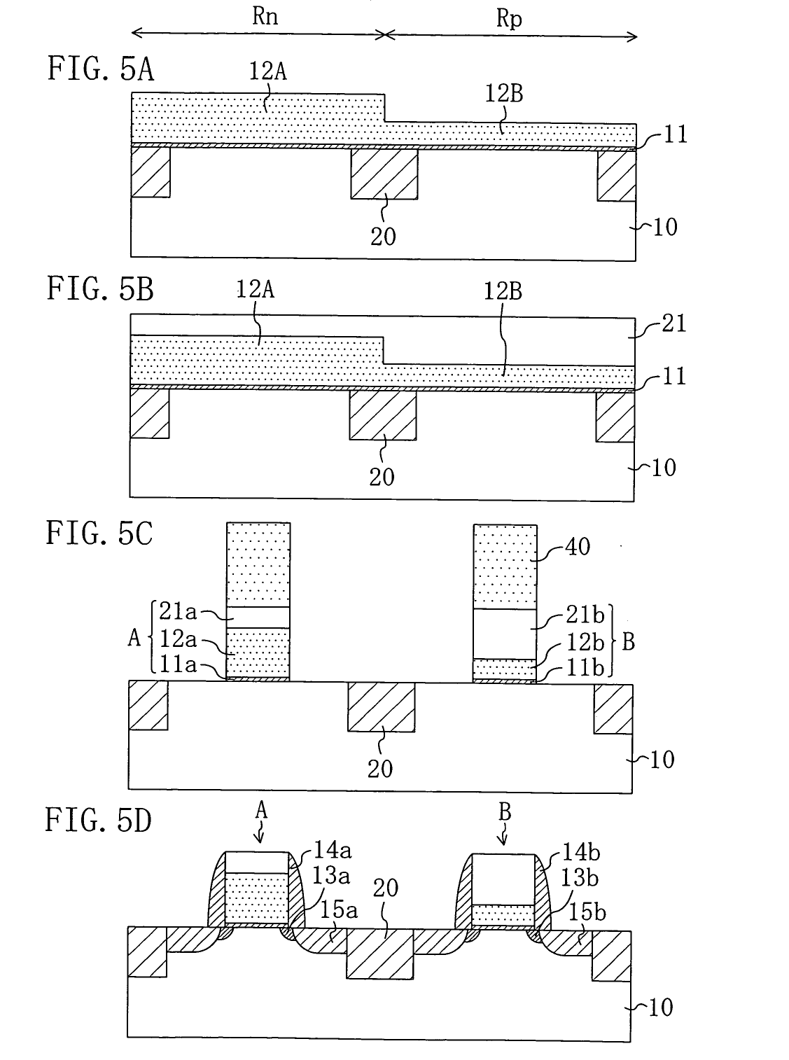

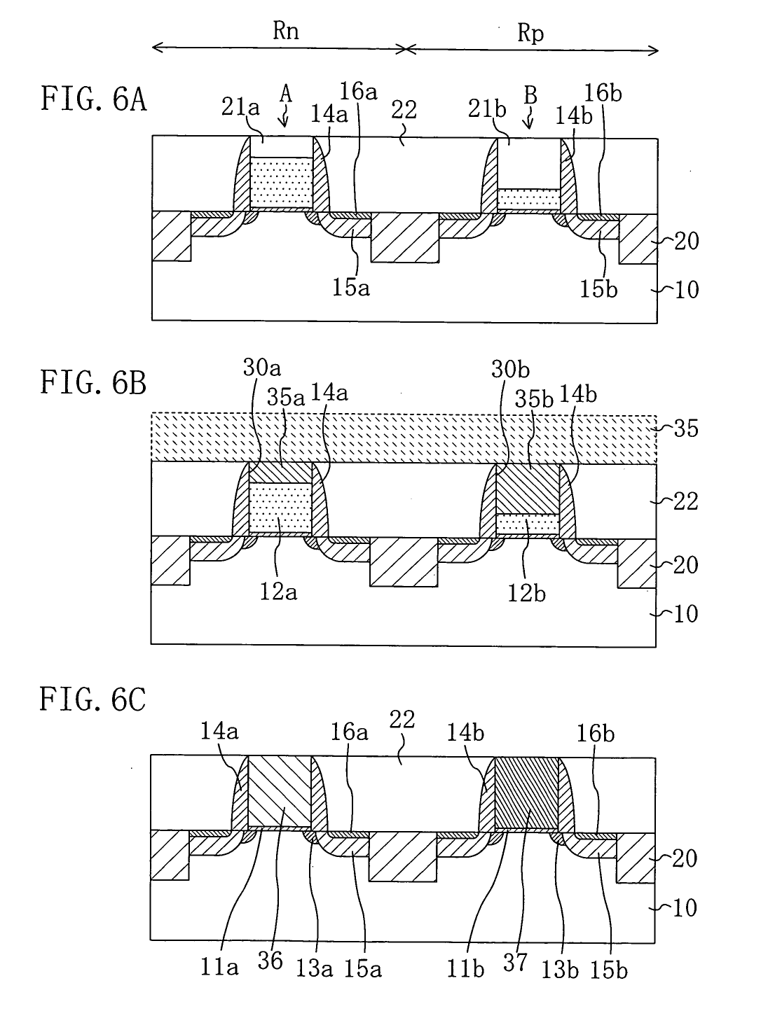

FIGS. 5A to 6C are step cross-sectional views schematically illustrating a method for fabricating a complementary semiconductor device according to the second embodiment. Each of the drawings shows an N-type MIS transistor formation region Rn on the left-hand side and a P-type MIS transistor formation region Rp on the right-hand side.

First, as shown in FIG. 5A, an isolation region 20 is formed in a semiconductor substrate 10 made of silicon to define the respective active areas of the N-type and P-type MIS transistor formation regions Rn and Rp. Then, a P-type well (not shown) is formed in the N-type MIS transistor formation region Rn of the semiconductor substrate 10 and an N-type well (not shown) is formed in the P-type MIS transistor formation region Rp of the semiconductor substrate 10.

Subsequently, a gate insulating film 11 made of a high dielectric constant material and having a thickness of 1.7 nm is formed on the semiconductor substrate 10. Then, a polysilicon film 12A with a first thickness is formed on the portion of the gate insulating film 11 which is located in the N-type MIS transistor formation region, while a polysilicon film 12B with a second thickness is formed on the portion of the gate insulating film 11 which is located in the P-type MIS transistor formation region. Preferably, the first thickness of the polysilicon film 12A in the N-type MIS transistor formation region Rn is adjusted to be larger than the second thickness of the polysilicon film 12B in the P-type MIS transistor formation region Rp. For example, the first thickness of the polysilicon film 12A is adjusted to be 70 nm, while the second thickness of the polysilicon film 12B is adjusted to be 40 nm.

The polysilicon films 12A and 12B having such different thicknesses are formed by, e.g., forming the polysilicon film 12A having the first thickness over the entire surface of the semiconductor substrate 10, forming a resist on the portion of the polysilicon film 12A which is located in the N-type MIS transistor formation region Rn, and then performing etching with respect to the portion of the polysilicon film 12A which is located in the P-type MIS transistor formation region Rp until it has a desired thickness. As a result, the polysilicon film 12B having the second thickness can be formed. Such an etching process allows easier control of an amount of etching than an etch-back process performed with respect to the portion of the polysilicon film which is located within the region surrounded by the sidewall insulating film, as disclosed in Non-Patent Document 2.

Next, as shown in FIG. 5B, a protective film 21 made of a CVD-oxide film with a thickness of 90 nm is formed entirely over the polysilicon films 12A and 12B having different thicknesses.

Next, as shown in FIG. 5C, a resist film 40 having a gate pattern configuration is formed on the protective film 21. Then, etching is performed successively with respect to the protective film 21, the polysilicon films 12A and 12B, and the gate insulating film 11 by using the resist film 40 as a mask, thereby forming a first gate portion A composed of a gate insulating film 11a, a silicon film 12a, and a protective film 21a on the portion of the semiconductor substrate 10 corresponding to the active area of the N-type MIS transistor formation region Rn, while simultaneously forming a second gate portion B composed of a gate insulating film 11b, a silicon film 12b, and a protective film 21b on the portion of the semiconductor substrate 10 corresponding to the active area of the P-type MIS transistor formation region Rp.

Next, as shown in FIG. 5D, n-type extension regions 13a are formed by self alignment relative to the first gate portion A in the surface of the portion of the semiconductor substrate 10 which is located in the N-type MIS transistor formation region Rn. On the other hand, p-type extension regions 13b are formed by self alignment relative to the second gate portion B in the portion of the semiconductor substrate 10 which is located in the P-type MIS transistor formation region Rp. Then, first and second sidewall insulating films 14a and 14b each made of a silicon nitride film are formed on the respective side surfaces of the first and second gate portions A and B. Thereafter, n-type source/drain regions 15a are formed by self alignment relative to the first sidewall insulating film 14a in the surface portions of the semiconductor substrate 10 which are located in the N-type MIS transistor formation region Rn. On the other hand, p-type source/drain regions 15b are formed by self alignment relative to the second sidewall insulating film 14b in the surface portions of the semiconductor substrate 10 which are located in the P-type MIS transistor formation region Rp.

Next, as shown in FIG. 6A, silicide films 16a and 16b each made of, e.g., a Ni silicide are formed by using a salicide technology on the n-type source/drain regions 15a and on the p-type source/drain regions 15b, respectively. Then, an insulating film 22 composed of a planarized CVD-oxide film is formed on the portion of the semiconductor substrate 10 on which the first and second gate portions A and B are not formed. The planarization can be performed by, e.g., depositing the insulating film 22 over the entire surface of the semiconductor substrate 10 and then polishing the insulating film 22 by CMP (Chemical Mechanical Polishing) until the respective upper surfaces of the protective films 21a and 21b are exposed.

Next, as shown in FIG. 6B, the protective films 21a and 21b are selectively removed from the first and second gate portion A and B such that the silicon films 12a and 12b are exposed at the respective bottom surfaces of depressed portions 30a and 30b surrounded by the first and second sidewall insulating films 14a and 14b, respectively. The selective removal of the protective films 21a and 21b can be effected by, e.g., performing etching using an etchant with a high selectivity with respect to each of the insulating film 22, the first and second sidewall insulating films 14a and 14b, and the silicon films 12a and 12b.

Thereafter, a metal film 35 with a thickness of 90 nm is formed over the entire surface of the semiconductor substrate 10 and then the portion (the region defined by the broken line in the drawing) of the metal film 35 which is located on the insulating film 22 is polished away by CMP such that metal films 35a and 35b buried only in the respective depressed portions 30a and 30b are formed. At this time, the portion of the metal film 35 which is located on the insulating film 22 need not necessarily be removed and may also be left, as shown by the broken line in the drawing. In this case, the upper surface of the metal film 35 is preferably planarized.

Next, as shown in FIG. 6C, a thermal process is performed with respect to the semiconductor substrate 10 to cause a reaction between the silicon film 12a and the metal film 35a and silicidation, thereby forming a first metal silicide film 36 on the gate insulating film 11a in the N-type MIS transistor formation region Rn. At the same time, the thermal process causes a reaction between the silicon film 12b and the metal film 35b and silicidation, thereby forming a second metal silicide film 37 on the gate insulating film 11b in the P-type MIS transistor formation region Rn.

Then, the respective upper surfaces of the first and second metal silicide films 36 and 37 are preferably planarized to be flush with the upper surface of the insulating film 22 by performing surface polishing using a CMP method. As a result, an N-type MIS transistor having a gate portion composed of the gate insulating film 11a and the first metal silicide film 35 is formed in the N-type MIS transistor formation region Rn. On the other hand, a P-type MIS transistor having a gate portion composed of the gate insulating film 11b and the second metal silicide film 37 is formed in the P-type MIS transistor formation region Rp.

At this stage, the first metal silicide film 36 constitutes the gate electrode of the N-type MIS transistor, while the second metal silicide film 37 constitutes the gate electrode of the P-type MIS transistor. By thus using the different metal silicide materials to compose the respective gate electrodes of the N-type and P-type MIS transistors, the threshold voltage of the complementary MIS transistor can be controlled to have a proper value.

In the method described above, the thickness ratios between the silicon films 12a and 12b and the metal films 35a and 35b are predetermined to provide the metal silicide films having desired different composition ratios in the N-type and P-type MIS transistors. For example, when each of the metal films 35a and 35b is made of a nickel (Ni) material, the film thickness ratios are preferably set such that the first metal silicide film 36 having a composition ratio represented by NiSi or Ni₂Si is formed in the N-type MIS transistor and the second metal silicide film 37 having a composition ratio represented by Ni₃Si is formed in the P-type MIS transistor.

In accordance with the present invention, the multilayer film including the silicon film 12a and the metal film 35a in the N-type MIS transistor formation region Rn and the multilayer film including the silicon film 12b and the metal film 35b in the P-type MIS transistor formation region Rp have equal heights defined by the first and second sidewall insulating films 14a and 14b, as shown in FIG. 6B. Therefore, even when the first and second metal silicide films 36 and 37 having different composition ratios are formed through silicidation, the level difference between the two metal silicide films can be reduced.

Since the polysilicon films 12A and 12B are formed to have precisely controlled thicknesses, the metal silicide films can be formed to have stable composition ratios.

When the thermal process is performed with the metal film 35 being formed also on the second insulating film 22, planarization is preferably performed by converting the silicon films 12a and 12b to the first and second metal silicide films 36 and 37 and then polishing away the portion of the metal film 35 which remains on the second insulating film 22 by CMP such that the respective upper surfaces of the first and second metal silicide films 36 and 37, the upper surface of the insulating film 22, and the upper ends of the first and second sidewall insulating films 14a and 14b are substantially flush with each other.

### Variation of Embodiment 2

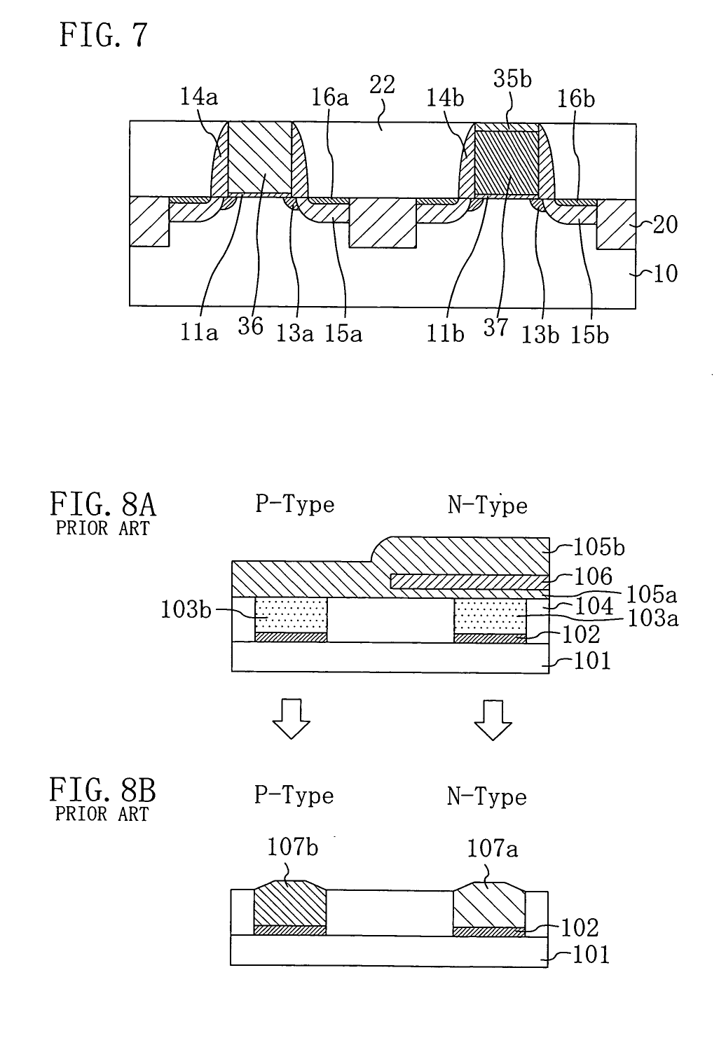

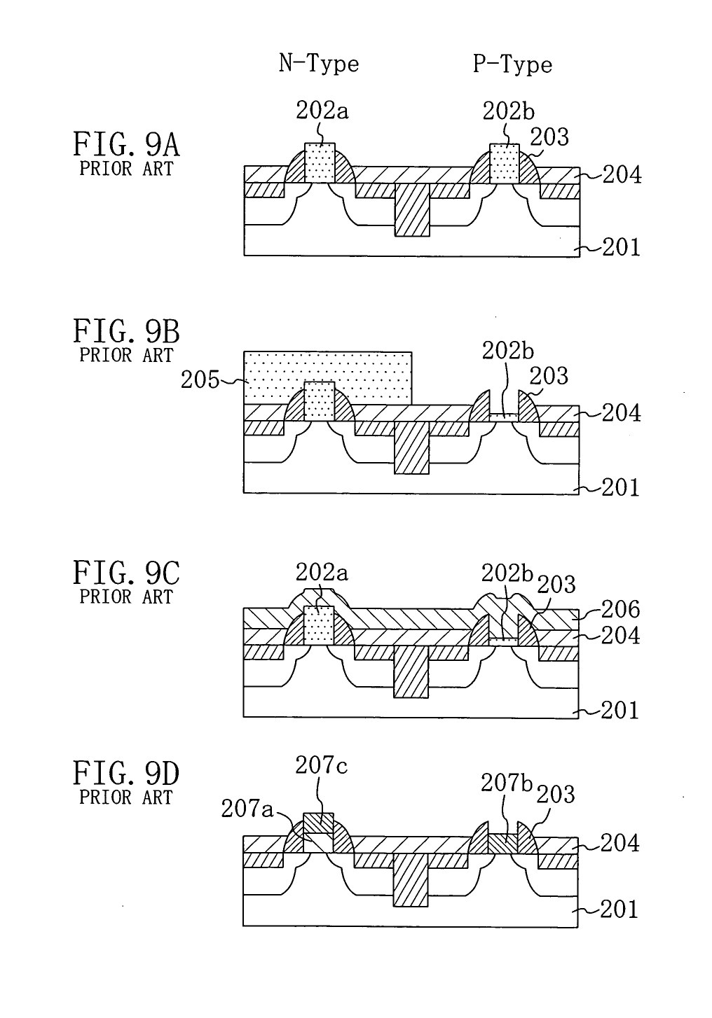

FIG. 7 is a cross-sectional view showing a complementary MIS transistor according to a variation of the second embodiment.

The complementary MIS transistor shown in FIG. 7 has the same structure as the complementary MIS transistor according to the second embodiment, except that the metal film 35b is formed on the second metal silicide film 37 of the P-type MIS transistor.

That is, as shown in FIG. 7, the gate electrode of the P-type MIS transistor is composed of the second metal silicide film 37 and the metal film 35b. The upper surface of the metal film 35b is planarized to be substantially flush with the upper surface of the first metal silicide film 36, the upper surface of the insulating film 22, and the respective upper ends of the first and second sidewall insulating films 14a and 14b.

The structure is obtained by setting the thickness of the silicon film 12b and the depth of the depressed portion 30b after the step shown in FIG. 6B such that the upper surface of the second metal silicide film formed by the thermal process in the step shown in FIG. 6C is lower than the upper surface of the insulating film 22 and thereby allowing the metal film 35b to remain on the second metal silicide film 37 of the P-type MIS transistor, as shown in FIG. 7. As a result, the N-type MIS transistor having the gate portion composed of the gate insulating film 11a and the first metal silicide film 36 is formed in the N-type MIS transistor formation region Rn, while the P-type MIS transistor having the gate portion composed of the gate insulating film 11b, the second metal silicide film 37, and the metal film 35b is formed in the P-type MIS transistor formation region Rp.

In the arrangement, the gate electrode of the P-type MIS transistor is made of the multilayer film including the second metal silicide film 37 and the metal film 35b. Therefore, when the resistance of the second metal silicide film 37 is higher than that of the first metal silicide film 36, an increase in the resistance of the gate electrode of the P-type MIS transistor can be prevented by using the metal film 35b.

Although each of the first and the second embodiments and the respective variations thereof has been described by using the complementary MIS transistor, the present invention is not limited thereto and can be applied also to two types of MIS transistors having the same conductivity type and different threshold voltages.

Although the present invention has been described thus far by using the preferred embodiments thereof, it will easily be appreciated that the description is not restrictive and various changes and modifications can be made to the present invention.

What is claimed is:

1. A semiconductor device comprising a first MIS transistor and a second MIS transistor, wherein
the first MIS transistor comprises:
a first gate portion having a first gate insulating film formed on a semiconductor substrate and a first gate electrode made of a first metal silicide film formed on the first gate insulating film;
a first sidewall insulating film formed on each of side surfaces of the first gate portion; and
an insulating film formed on the semiconductor substrate in lateral relation to the first sidewall insulating film and
the second MIS transistor comprises:
a second gate portion having a second gate insulating film formed on the semiconductor substrate and a second gate electrode made of a second metal silicide film formed on the second gate insulating film;
a second sidewall insulating film formed on each of side surfaces of the second gate portion; and
the insulating film formed on the semiconductor substrate in lateral relation to the second sidewall insulating film, wherein
respective upper surfaces of the first and second gate portions are planarized to be flush with an upper surface of the insulating film.

2. The semiconductor device of claim 1, wherein the first gate portion is made of the first gate insulating film, the first gate electrode, a protective insulating film formed on the first gate electrode, and a metal film formed on the protective insulating film.

3. The semiconductor device of claim 2, wherein the second gate portion is made of the second gate insulating film, the second gate electrode, and a third sidewall insulating film formed on an upper portion of each of inner side surfaces of the second sidewall insulating film.

4. The semiconductor device of claim 2, wherein the second gate portion further comprises the metal film formed on the second metal silicide film.

5. The semiconductor device of claim 1, wherein an upper surface of the first metal silicide film is lower in level than an upper surface of the second metal silicide film.

6. The semiconductor device of claim 1, wherein
the first gate portion is made of the first gate insulating film and the first gate electrode and
the second gate portion is made of the second gate insulating film and the second metal silicide film.

7. The semiconductor device of claim 1, wherein
the first gate portion is made of the first gate insulating film and the first gate electrode and
the second gate portion is made of the second gate insulating film, the second metal silicide film, and a metal film formed on the second metal silicide film.

8. The semiconductor device of claim 1, wherein the second metal silicide film is metal-richer than the first metal silicide film.

9. The semiconductor device of claim 1, wherein the first meal silicide film is made of NiSi or Ni₂Si and the second metal silicide film is made of Ni₃Si.

10. The semiconductor device of claim 1, wherein
the first MIS transistor is an N-type MIS transistor and
the second MIS transistor is a P-type MIS transistor.

11. A method for fabricating a semiconductor device comprising a first MIS transistor having a first gate portion and a second MIS transistor having a second gate portion, the method comprising the steps of:
(a) forming, on a semiconductor substrate, the first gate portion made of a first gate insulating film, a first silicon film, and a first protective film and the second gate portion made of a second gate insulating film, a second silicon film, and a second protective film;
(b) forming a first sidewall insulating film on each of side surfaces of the first gate portion and forming a second sidewall insulating film on each of side surfaces of the second gate portion;
(c) after the step (b), forming an insulating film on the semiconductor substrate and then planarizing the insulating film to expose respective upper surfaces of the first and second protective films;
(d) after the step (c), selectively removing the first and second protective films from the first and second gate portions;
(e) after the step (d), siliciding the entire first silicon film to form a first metal silicide film;
(f) after the step (d), siliciding the entire second silicon film to form a second metal silicide film; and
(g) after the steps (e) and (f), planarizing respective upper surfaces of the first and second gate portions such that they are flush with an upper surface of the insulating film, wherein
the first gate portion of the first MIS transistor has the first gate insulating film and a first gate electrode made of the first metal silicide film and
the second gate portion of the second MIS transistor has the second gate insulating film and a second gate electrode made of the second metal silicide film.

12. The method of claim 11, wherein
the step (e) includes the step of siliciding the entire second silicon film to form a metal silicide film, while simultaneously forming the first metal silicide film, each through silicidation using a first metal film, the method further comprising the step of:
(h) after the step (e) and before the step (f), forming a protective insulating film covering an upper surface of the first metal silicide film, wherein
the step (f) includes the step of converting the metal silicide film to the second metal silicide film through silicidation using a second metal film,
the step (g) includes the step of performing planarization by polishing away the portion of the second metal film which is located on the insulating film and thereby locally leaving the second metal film on the protective insulating film,
the first gate portion of the first MIS transistor is made of the first gate insulating film, the first gate electrode, the protective insulating film formed on the first gate electrode, and the second metal film formed on the protective insulating film, and
the second gate portion of the second MIS transistor is made of the second gate insulating film and the second gate electrode.

13. The method of claim 12, wherein
the step (g) includes the step of polishing away the portion of the second metal film which is located on the insulating film and thereby locally leaving the second metal film on the second metal silicide film, and
the second gate portion of the second MIS transistor is made of the second gate insulating film, the second gate electrode, and the second metal film.

14. The method of claim 11, further comprising the steps of:
(i) before the step (a), forming a gate insulating film on the semiconductor substrate;
(j) forming, on the gate insulating film, a first silicon forming film having a first thickness and a second silicon forming film having a second thickness smaller than the first thickness; and
(k) forming a protective film having a planarized surface over the first and second silicon forming films, wherein
the step (a) includes the step of patterning the protective film, the first and second silicon forming films, and the gate insulating film to form the first and second protective films each made of the protective film, the first silicon film made of the first silicon forming film, the second silicon film made of the second silicon forming film, and the first and second gate insulating films each made of the gate insulating film,
the steps (e) and (f) include the step of performing silicidation by using a metal film to simultaneously form the first and second metal silicide films, and
the step (g) includes performing planarization by polishing away the portion of the metal film which is located on the insulating film.

15. The method of claim 14, wherein
the step (g) includes the step of polishing away the portion of the metal film which is located on the insulating film and thereby leaving the metal film on the second metal silicide film and
the second gate portion of the second MIS transistor is made of the second gate insulating film, the second gate electrode, and the metal film.

16. The method of claim 11, wherein the second metal silicide film is metal-richer than the first metal silicide film.

17. The method of claim 16, wherein the first meal silicide film is made of NiSi or Ni₂Si and the second metal silicide film is made of Ni₃Si.

18. The method of claim 11, wherein
the first MIS transistor is an N-type MIS transistor and
the second MIS transistor is a P-type MIS transistor.
